(19) United States
(12) Patent Application Publication
(10) Pub. No.: US 2020/0203400 A1
(43) Pub. Date: Jun. 25, 2020

(54) PROCESS FOR FABRICATING A PLURALITY OF DIODES FROM A READOUT SUBSTRATE

(71) Applicant: Commissariat A L'Energie Atomique et aux Energies Alternatives, Paris (FR)

(72) Inventors: Jerome Le Perchec, Grenoble Cedex (FR); Cyril Cervera, Grenoble Cedex (FR); Carole Pernel, Grenoble Cedex (FR)

(73) Assignee: Commissariat A L'Energie Atomique et aux Energies Alternatives, Paris (FR)

(21) Appl. No.: 16/722,266

(22) Filed: Dec. 20, 2019

(30) Foreign Application Priority Data
Dec. 21, 2018 (FR) 18 73790

(51) Int. Cl. H01L 27/144; H01L 27/15; H01L 31/028; H01L 31/0296; H01L 31/0304; H01L 31/0312; H01L 33/32; H01L 31/18; H01L 33/00

(52) U.S. Cl. CPC H01L 27/1446; H01L 33/007; H01L 31/028; H01L 31/0296; H01L 31/02966; H01L 31/03046; H01L 31/0312; H01L 33/32; H01L 31/1804; H01L 31/1828; H01L 31/1832; H01L 31/1836; H01L 31/1844; H01L 31/1852; H01L 31/1812; H01L 27/156

(57) ABSTRACT

The invention relates to a process for fabricating an optoelectronic device (1) comprising a plurality of diodes (40), comprising the following steps:
providing a readout substrate (10) containing a readout circuit (12) and having a growth face defined by a plurality of conductive segments (20) that are separate from one another and connected to the readout circuit (12);
producing, on the growth face, a plurality of nucleation segments (30) made of a two-dimensional crystalline material, which segments are separate from one another, said segments resting in contact with the conductive segments (20);
producing, by epitaxy from the nucleation segments (30), the plurality of diodes.

### TECHNICAL FIELD

The field of the invention is that of optoelectronic devices comprising a matrix array of photodiodes or of light-emitting diodes, and notably relates to a process for fabricating such an optoelectronic device from a readout substrate. The invention is notably applicable to the field of photodetection of infrared radiation.

### PRIOR ART

Processes for fabricating optoelectronic devices comprising matrix arrays of diodes generally comprise a hybridizing step, in which two microelectronic chips are mechanically joined and electrically connected to each other. The microelectronic chips may then be an optoelectronic chip comprising the matrix array of diodes, and a control chip comprising a readout circuit that reads and/or controls the diodes. The diodes may be photodiodes or light-emitting diodes. Various approaches to hybridization exist, as notably described in the article by A. Rogalski entitled “Progress in focal plane array technologies”, Progress in Quantum Electronics 36 (2012) 342-473.

A first approach thus consists in hybridizing the microelectronic chips using interconnect pads, indium bumps for example. The microelectronic chips are then joined via their respective connection faces, each chip comprising on said face a matrix array of electrical interconnect pads. The hybridizing process then comprises a step of aligning and bringing the interconnect pads into contact, pairwise, followed by a step of applying a temperature, called the hybridizing temperature, so as to thus produce a mechanical joint between the two chips via fusion or inter-diffusion of the interconnect pads of each and/or both microelectronic chips. However, with such a fabricating process, there is a risk of misalignment between the interconnect pads, which may then lead to a loss of mechanical contact and therefore a faulty electrical connection between the respective interconnect pads. This risk increases as the number of diodes of low pitch in the matrix array of diodes increases.

Another hybridizing approach, called the loophole approach, consists in joining an optoelectronic chip comprising a stack of semiconductor layers intended to form the diodes to a control chip by means of an intermediate bonding layer. Through-diodes are then produced by local etching of the semiconductor stack and doping of the sidewalls of the trenches. The trenches open onto connection pads of the command chip and are metallized in order to electrically connect the diodes and the readout circuit. However, the bond efficiency must be optimal over all the area between the bonded microelectronic chips, this being especially difficult to achieve when the matrix array of diodes is large. Specifically there is a risk of localized debonding between the microelectronic chips, which may then lead to a faulty electrical connection between the diodes and the readout circuit.

There is therefore a need to provide a fabricating process that allows the risk of loss of mechanical contact and therefore of faulty electrical connection between the diodes and the readout circuit to be decreased, notably when the matrix array of diodes comprises a high number of diodes of low pitch. There is also a need for diodes made of a semiconductor having a high crystal quality, and therefore a high quantum efficiency.

Document WO2015/044619A1, which describes a plurality of light-emitting diodes taking the form of nanowires grown epitaxially from a growth substrate is also known. This growth substrate is made of a crystalline semiconductor. The readout circuit, which comprises metal lines, is located on the exterior and not in the interior of this growth substrate.

### SUMMARY OF THE INVENTION

The objective of the invention is to at least partially remedy the drawbacks of the prior art, and more particularly to provide a method allowing an optoelectronic device comprising a plurality of diodes to be fabricated, and allowing the risk of loss of mechanical contact and therefore of faulty electrical connection between the diodes and readout circuit to be avoided.

The fabricating process according to the invention also allows diodes made of semiconductor the crystal quality of which is high to be obtained, thus allowing the optical and/or electronic performance of the optoelectronic device to be improved.

To this end, one subject of the invention is a process for fabricating an optoelectronic device comprising a plurality of diodes, comprising the following steps:
providing a readout substrate containing a readout circuit comprising metal lines separated from one another by so-called inter-metal dielectric layers, and having a growth face defined by a plurality of conductive segments made of at least one metal, which segments are separate from one another and connected to the readout circuit;
producing, on the growth face, a plurality of nucleation segments made of a two-dimensional crystalline material, which segments are separate from one another, said segments resting in contact with the conductive segments;
producing, by epitaxy from the nucleation segments, the plurality of diodes.

In other words, the growth substrate is a readout substrate that is functionalized by the presence of the readout circuit, and then is called a readout substrate. The latter therefore comprises a plurality of metal lines extending over a plurality of interconnect levels, which are separated from one another by inter-metal dielectric layers and are connected to one another by metal vias. The growth substrate thus differs from the substrate of document WO2015/044619A1 in that it comprises such a readout circuit. To ensure the nucleation and epitaxial growth of the crystalline material of the diodes, the nucleation segments are made of a two-dimensional crystalline material, i.e. it is formed from one or more monolayers, each monolayer having a two-dimensional crystal lattice rather than a three-dimensional crystal lattice.

The following are certain preferred but nonlimiting aspects of this fabricating process.

The readout substrate may have a planar upper face, the conductive segments protruding with respect to the planar upper face.

The readout substrate may have a planar upper face, the conductive segments lying flush with the planar upper face.

The conductive segments may rest in contact with segments of the metal lines of the readout circuit or form segments of the metal lines of this readout circuit.

Each conductive segment may comprise:
a zone, referred to as the main zone, coated with the nucleation segment, and intended to be coated with the diode, and
a zone, called the lateral zone, partially coated with the nucleation segment so that the latter has a lateral face connecting lower and upper faces of the nucleation segment, and intended not to be coated with the diode and extending, in a plane parallel to the readout substrate, from the main zone,
the process comprising a step of producing a portion, called the lateral upper portion, of the conductive segment so that it makes continuous contact with the lateral zone and continuous contact with the lateral face of the nucleation segment. The lateral upper portion may also make contact with a lower surface of a lateral face of the diode.

The fabricating process may comprise the following steps:
providing the growth substrate, so that each conductive segment comprises a main zone and a lateral zone extending, in a plane parallel to the readout substrate, from the main zone;
producing the plurality of nucleation segments, so that each main zone is coated with the nucleation segment, and so that each lateral zone is partially coated with the nucleation segment, each nucleation segment thus having a lateral face located above the lateral zone of the conductive segment, connecting a lower face of the nucleation segment making contact with the conductive segment to an opposite upper face;
producing a lateral upper portion of the conductive segment, making contact with the zone thereof not coated with the nucleation segment, and contact with the lateral face of the nucleation segment;
producing the plurality of diodes, so that each diode coats only the main zone and not the lateral zone of the conductive segment.

Each conductive segment may comprise:
a zone, called the main zone, coated with the nucleation segment and with the diode, and
a zone, called the lateral zone, not coated with the diode, and extending, in a plane parallel to the readout substrate, from the main zone,
the process comprising a step of producing a portion, called the lateral upper portion, of the conductive segment so that it makes continuous contact with the lateral zone and continuous contact with a lower surface of a lateral face of the diode. The lateral upper portion may also make contact with the lateral face of the nucleation segment.

The fabricating process may comprise the following steps:
providing the growth substrate, so that each conductive segment comprises a main zone and a lateral zone extending, in a plane parallel to the readout substrate, from the main zone;
producing the plurality of nucleation segments, so that each main zone is coated with the nucleation segment, and so that each lateral zone is partially coated with the nucleation segment, each nucleation segment thus having a lateral face located above the lateral zone of the conductive segment, connecting a lower face of the nucleation segment making contact with the conductive segment to an opposite upper face;
producing the plurality of diodes, so that each diode coats only the main zone and not the lateral zone of the conductive segment;
producing a lateral upper portion of the conductive segment, so that it makes contact with the zone thereof not coated with the nucleation segment, and contact with a lower surface of a lateral face of the diode.

The process may comprise, prior to the step of producing the lateral upper portion, a step of partially etching the diodes isotropically and selectively from a lateral face of the diodes, the lateral face of the diodes connecting a lower face making contact with the nucleation segments and an opposite upper face, so that the lower surface is inclined with respect to an axis orthogonal to the plane of the readout substrate.

The process may comprise a step of producing an intermediate insulating layer, making contact with the diodes in a plane parallel to the readout substrate, and filling the space between the diodes.

The intermediate insulating layer may comprise a passivating sublayer making contact with a lateral face of the diodes, and a filling layer covering the passivating sublayer and filling the inter-diode space.

The invention also relates to an optoelectronic device, comprising:
a readout substrate, containing a readout circuit, and comprising a plurality of conductive segments that are made of at least one metal, said conductive segments being separate from one another, defining a growth face of the readout substrate and being connected to the readout circuit, the latter comprising metal lines that are separated from one another by dielectric layers called inter-metal dielectric layers;
a plurality of nucleation segments, which are separate from one another, placed in contact with the conductive segments and made of a two-dimensional crystalline material;
a plurality of diodes, located in contact with the nucleation segments.

The diodes may be based on a semiconductor of interest, which is an element or a compound of II-VI, III-V or IV type.

Each conductive segment may comprise a lateral zone that is partially coated by the nucleation segment, and a portion, called the lateral upper portion, that makes continuous contact with the lateral zone and continuous contact with a lateral face of the nucleation segment.

Each conductive segment may comprise a lateral zone not coated with a diode, and a portion, called the lateral upper portion, that makes continuous contact with the lateral zone and continuous contact with a lower surface of a lateral face of the diode.

At least two diodes may be made of a semiconductor having different compositions.

### BRIEF DESCRIPTION OF THE DRAWINGS

Other aspects, aims, advantages and features of the invention will become more clearly apparent on reading the following detailed description of preferred embodiments thereof, which description is given by way of nonlimiting example with reference to the appended drawings, in which:

FIGS. 1A and 1B are partial schematic views in cross section of two optoelectronic devices according to two variant embodiments, in which the conductive segments lie flush with the planar upper face of the readout substrate

(FIG. 1A) or protrude with respect to the planar upper face (FIG. 1B);

FIGS. 2A to 2G illustrate, schematically and partially, various steps of a process for fabricating an optoelectronic device according to one variant of the embodiment illustrated in FIG. 1A, in which variant the conductive segments protrude with respect to the planar upper face of the readout substrate;

FIGS. 3A to 3D illustrate, schematically and partially, various steps of a process for fabricating the optoelectronic device according to the embodiment illustrated in FIG. 1B, in which embodiment the intermediate insulating layer comprises a lower portion located between the conductive segments and the nucleation segment;

FIGS. 4A to 4D illustrate, schematically and partially, seen in cross section and from above, various steps of a process for fabricating an optoelectronic device according to one embodiment, in which each conductive segment is formed from two lateral portions encapsulating a lateral portion of the corresponding nucleation segment;

FIGS. 5A to 5D illustrate, schematically and partially, various steps of a process for fabricating an optoelectronic device according to one embodiment, in which each conductive segment comprises a lateral upper portion that makes contact with an inclined lower surface of the lateral face of the corresponding diode.

### DETAILED DESCRIPTION OF PARTICULAR EMBODIMENTS

In the figures and in the rest of the description, the same references have been used to reference elements that are identical or similar. In addition, the various elements are not shown to scale for the sake of clarity of the figures. Moreover, the various embodiments and variants are not exclusive of one another and may be combined together. Unless otherwise indicated, the terms “substantially”, “about” and “of the order of” mean to within 10% and preferably to within 5%.

The invention relates to a process for fabricating an optoelectronic device comprising a plurality of diodes from a readout substrate. The diodes are formed by van der Waals epitaxy from nucleation segments made of a two-dimensional crystalline material.

Generally, van der Waals epitaxy is a heteroepitaxial technique via which a crystalline semiconductor layer is produced on a nucleation layer formed from one or more monolayers of a two-dimensional crystalline material, the layer being bonded thereto by van der Waals bonds and not by covalent or ionic bonds. Van der Waals epitaxy notably makes it possible to decrease the effect of the lattice mismatch that may exist between the two-dimensional crystalline material and the epitaxially grown crystal layer, this lattice mismatch being the result of the difference between the lattice parameters of the two materials, this thus allowing a relaxed or quasi-relaxed epitaxially grown crystal layer to be obtained. Such a crystal layer obtained by van der Waals epitaxy then has a low density of structural defects such as misfit dislocations, thus optimizing the optical and/or electronic properties of the epitaxially grown crystal layer.

The material of the nucleation layer is a crystalline material that is said to be two-dimensional in so far as it is formed from one or more monolayers or a plurality of monolayers that are stacked on one another and bonded to one another by weak interactions, each monolayer being formed from atoms or molecules arranged so as to form a two-dimensional crystal lattice. A monolayer is a two-dimensional crystalline structure of monatomic thickness. The two-dimensional material may be chosen among chalcogenides of transition metals, such as molybdenum sulfide or selenide (MoS₂, MoSe₂) or tungsten sulfide (WS₂), graphene, the boron nitride of two-dimensional structure (hexagonal boron nitride), inter alia. The potential monolayers of the nucleation layer are bonded to one another by weak bonds of van der Waals type. In addition, the nucleation layer is bonded to the material of the subjacent conductive layer by weak bonds of van der Waals type, and not by covalent or ionic bonds. It is bonded to the semiconductor of the diodes also by weak bonds of van der Waals type.

Generally, the diodes of the optoelectronic device may be photodiodes or light-emitting diodes, which are for example mainly based on a semiconductor of interest, which may be a semiconductor element or semiconductor compound of III-V, IV or II-VI type. Thus, by way of example, in the case of photodiodes, the semiconductor of interest may notably be chosen: from the elements of columns II and VI of the periodic table of the elements, CdHgTe, CdTe or HgTe for example; among the elements of columns III and V, InGaAs and alloys based on antimony Sb for example; or even among the elements of column IV, such as silicon, germanium, tin in its semiconductor phase, and alloys formed from these elements, SiGe, GeSn and SiGeSn for example. In the case of light-emitting diodes, the semiconductor of interest may be a III-V semiconductor compound based on GaN. In other words, the diode is made of a semiconductor at least 50% of the volume of which is formed or comprises GaN or an alloy of GaN, InGaN or AlGaN for example.

For the sake of clarity, examples of optoelectronic devices comprising a plurality of diodes obtained using a fabricating process according to various variant embodiments will firstly be illustrated.

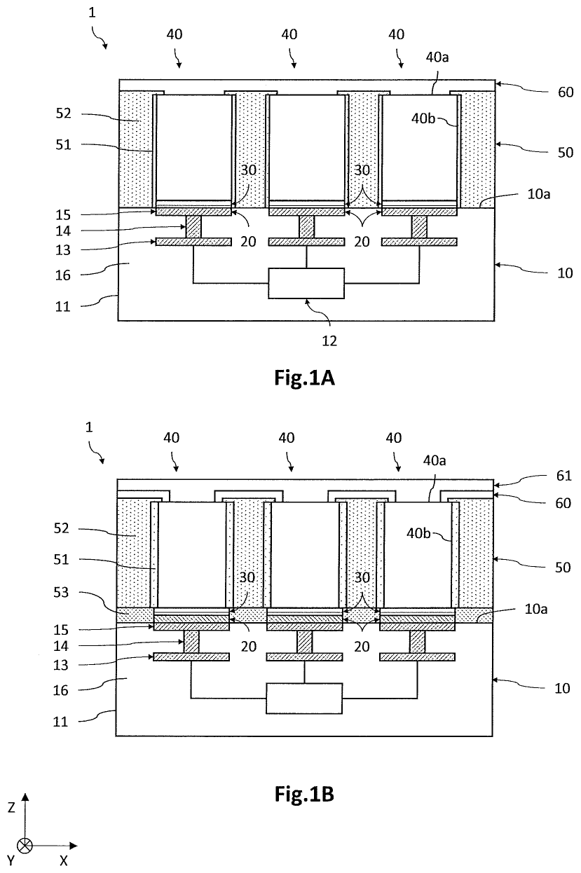

FIGS. 1A and 1B are schematic and partial cross-sectional views of two examples of an optoelectronic device 1 obtained according to various variants of a fabricating process.

Generally, the optoelectronic device 1 comprises:
a functionalized substrate called the readout substrate 10, which contains a readout circuit 12, and comprises a plurality of conductive segments 20, which are separate from one another, define a growth face of the readout substrate 10 and are connected to the readout circuit 12;
a plurality of nucleation segments 30, which are separate from one another, placed in contact with the conductive segments 20, and made of a two-dimensional crystalline material;
the plurality of diodes 40, which are produced by van der Waals epitaxial growth from the nucleation segments 30.

Here a three-dimensional orthogonal direct coordinate system XYZ, in which the X and Y axes form a plane parallel to the main plane of the readout substrate 10, and in which the Z axis is oriented substantially orthogonal to the main plane of the readout substrate 10, will be defined—this coordinate system will be referred to in the rest of the description. In the rest of the description, the terms “lower” and “upper” are to be understood to be relative to positions that are nearer to and further from the readout substrate 10 in the +Z direction.

The readout substrate 10 is formed from a carrier substrate 11 containing the readout circuit 12, which is a CMOS circuit suitable for controlling and reading the diodes 40. The readout substrate 10 has a face, called the growth face, from which the diodes 40 are produced. It furthermore comprises a plurality of conductive segments 20, which are separate from one another, which define the growth face of the readout substrate 10 and which are connected to the readout circuit 12.

The readout circuit 12 thus comprises active or passive electronic elements, such as diodes, transistors, capacitors, resistors, etc., that are electrically connected by metal interconnects to the diodes 40. It comprises an upper electrical interconnect level comprising segments 15 of a metal line, which is electrically connected to segments 13 of metal line of a lower electrical interconnect level by conductive vias 14. The vias and the metal lines are separated from one another by inter-metal dielectric layers 16. The readout substrate 10 here comprises a planar upper face 10a with which the conductive segments 15 of the metal line of the last interconnect level, and the inter-metal dielectric layer 16 lie flush. By way of illustration, the conductive vias 14 and the conductive segments 13, 15 of the metal lines may be made of copper, of aluminium or of tungsten, using a damascene process in which trenches produced in the inter-metal dielectric layer 16 are filled with copper. The copper or tungsten may optionally be inserted transversely between vertical layers made of titanium nitride or tantalum nitride, inter alia. A chemical-mechanical-polishing (CMP) technique may be used to make the conductive segments 15 flush with the planar upper face 10a of the readout substrate 10.

The growth face is defined by a plurality of conductive segments 20, which are made of at least one electrically conductor, a metal for example, and which are separate from one another and connected to the readout circuit 12. The conductive segments 20 are said to be separate from one another in the sense that they are physically separate and electrically insulated from one another in the XY plane. Each conductive segment 20 is intended to raise a diode 40 to an electrical potential set by the readout circuit 12, thus allowing charge carriers to be injected into or collected from the diode 40. As illustrated in the figures, the conductive segments 20 may protrude with respect to a plane passing through a planar upper face 10a of the readout substrate 10, or lie flush with the planar upper face 10a. By flush, what is meant is “to be at the same level as” or “to extend from”.

Thus, FIG. 1A illustrates an example in which the conductive segments 20 are the segments 15 of the metal line of the last interconnection level, which segments lie flush with the planar upper face 10a of the readout substrate 10. They are separated from one another in the XY plane by the inter-metal dielectric layer 16.

FIG. 1B illustrates another example in which the conductive segments 20 are metal pads located in contact with the segments 15 of the metal line of the last interconnect level, the latter segments lying flush with the planar upper face 10a of the readout substrate 10. The conductive segments 20 are pads made of at least one metal, for example gold, copper, aluminium, platinum and/or TiN, inter alia. They are separate from one another in the XY plane. They have dimensions in the XY plane that depend on the lateral dimensions desired for the diodes 40. The lateral dimensions may be comprised between 500 nm and a few millimetres, depending on the intended applications of the diodes 40, and are preferably comprised between 1 μm and 10 μm. They have a thickness, along the Z axis, that is for example comprised between 50 nm and 1 μm.

The optoelectronic device 1 comprises a plurality of nucleation segments 30, allowing the nucleation and epitaxial growth of the diodes 40. They are separate from one another, in the sense that they are physically separate and electrically insulated from one another in the XY plane. They are placed in contact with the conductive segments 20, and may thus participate in the injection of charge carriers into the diodes 40 or in the collection of the photogenerated charge carriers. They have lateral dimensions in the XY plane that are preferably substantially equal or even smaller than those of the conductive segments 20.

The nucleation segments 30 are formed from one or more monolayers of a two-dimensional crystalline material. This two-dimensional material is chosen depending on the semiconductor of interest of the diodes 40. Thus, when the latter is a II-VI alloy, the two-dimensional material is preferably chosen from graphene or a dichalcogenide of a transition metal, such as MoS₂, MoSe₂, WSe₂, MoTe₂, WTe₂, ZrS₂, TiS₂, inter alia. In the case where the two-dimensional material is a III-V alloy, the two-dimensional material is preferably chosen from graphene, a dichalcogenide of a transition metal, or even a monochalcogenide, notably one based on Ga, Te or Se, for example GaSe, GaTe or InSe, in particular when the semiconductor of interest is based on Ga, Te or Se, respectively. Preferably, the nucleation segments 30 are made of molybdenum sulfide or tungsten sulfide, and the conductive layers 20 are made of gold. Thus a higher adhesion is obtained.

The optoelectronic device 1 comprises a matrix array of diodes 40, which each comprise a pn or pin semiconductor junction, or even a so-called “barrier” diode junction (for example a pBn or nBn junction). The diodes 40 are photodiodes or light-emitting diodes. They may be suitable for detecting or emitting electromagnetic radiation of interest, for example in the infrared or visible. Generally, the diodes 40 comprise a n-doped semiconductor portion and a p-doped semiconductor portion, between which there may be an intrinsic (unintentionally doped) portion. The diodes 40 may have a conventional structure, which is not described in greater detail here. As known per se, the semiconductor junction may be formed by two doped semiconductor portions stacked on top of each other, these portions optionally being separated from each other by an active zone that optionally contains quantum wells. It may also be formed by a locally doped well located at the surface of a semiconductor portion.

The diodes 40 are based on the semiconductor of interest, and for example based on CdTe, InGaAs, antimony Sb, GaN Si and/or Ge, etc. They each comprise a lower face located in contact with the nucleation segments 30, an upper face 40a that is opposite along the Z axis and that forms an optical reception or emission face, and a lateral face 40b that connects the upper and lower faces together and transversely bounds the diode in the XY plane. The diodes 40 may have various shapes in the XY plane, for example a polygonal shape (for example a square, rectangular, triangular or hexagonal shape) or even a circular or oval shape. The diameter of the diodes 40 is here a quantity associated with its perimeter in a cross section in the XY plane. The diameter of each diode 40 may be constant along the Z axis, or may even vary in the +Z direction. The dimensions are preferably identical, from one diode to the next. The lateral dimensions, in the XY plane, may be comprised between 500 nm and a few millimetres, depending on the intended applications, and are preferably comprised between 1 μm and 10 μm.

The optoelectronic device 1 comprises an intermediate insulating layer 50, which makes contact with each diode 40 in the XY plane and fills the inter-diode space. This layer 50 preferably extends along the Z axis the entire length of the lateral faces 40b of the diodes 40, here from the growth face of the readout substrate 10. It advantageously passivates the sidewalls of the diodes 40, thus making it possible to decrease the surface component of the dark current of photodiodes or to decrease the effect of possible surface states that could lead to non-radiative recombination in light-emitting diodes. Thus, the optical and/or electronic properties of the diodes 40 are improved. The intermediate insulating layer 50 is formed from at least one electrical insulator, a dielectric for example, that may depend on the semiconductor of interest of the diodes 40. It electrically insulates the diodes 40 from one another in the XY plane. It may be formed from a single electrical insulator, or may be formed from various layers made of different materials, for example a passivating sublayer 51 covered by a filling layer 52.

Thus, FIG. 1A illustrates an example in which the intermediate insulating layer 50 is formed from a passivating sublayer 51 that makes contact with and covers the lateral face 40b of the diodes 40, and from a filling layer 52 that covers the passivating sublayer 51 and fills the inter-diode space in the XY plane. In this example, the intermediate insulating layer 50 extends from the readout substrate 10 along the Z axis: it therefore physically isolates and electrically insulates not only the nucleation segments 30 from one another, but also the diodes 40 from one another. The intermediate insulating layer 50 may be made of various (passivation and filling) materials. By way of example, when the diodes 40 are based on CdHgTe, the passivating sublayer 51 may be made of CdTe, and the filling layer 52 may be made of ZnS, SiO or SiN, inter alia.

FIG. 1B illustrates another example in which the intermediate insulating layer 50 comprises a lower insulating portion 53 and an upper insulating portion that are stacked on each other along the Z axis. More precisely, the lower insulating portion 53 here makes contact and extends from the growth face along the Z axis, and extends between and makes contact with the conductive segments 20 and the nucleation segments 30. It may notably correspond to a growth mask used during the epitaxy of the diodes 40. It has a thickness at least equal to the thickness of the conductive segments 20 and of the nucleation segments 30. The lower insulating portion 53 may be made of at least one dielectric, for example a silicon oxide SiO or a silicon nitride SiN, inter alia.

The upper insulating portion extends along the Z axis from the lower insulating portion 53, and extends, in the XY plane, between the diodes 40 and makes contact therewith. It is here formed from a passivating underlayer 51 located in contact with the lateral faces, and from a filling layer 52. By way of example, when the diodes 40 are made of a III-V semiconductor, InSb for example, the passivating sublayer 51 may be an oxide of the III-V semiconductor, for example obtained by electrochemical oxidation of the III-V semiconductor, and the filling layer 52 may be a silicon oxide or nitride that covers the passivating sublayer 51 and fills the space between the diodes 40 in the XY plane.

The optoelectronic device 1 comprises an upper biasing electrode, here taking the form of an upper conductive layer 60 making contact with the upper face 40a of each diode 40, and connected to the readout circuit 12. The upper conductive layer 60 is made of a least one electrical conductor. It may thus be a question of ITO, of optionally doped ZnO, of perovskites such as SrTiO₃ and Cd₃TeO₆, of doped CdO, of optionally doped In₂O₃, of TiO₂, of VO₂, inter alia. It may extend so as to continuously cover the upper faces 40a of the diodes 40 (FIG. 1A) and will then be made of one or more conductors that are transparent to the electromagnetic radiation of interest. By transparent, what is meant is a transmission coefficient higher than or equal to 50% at a central wavelength of the electromagnetic radiation of interest. This layer may also extend over the upper faces 40a of the diodes 40 partially (FIG. 1B), and in particular over the borders thereof, so as to decrease potential optical absorption. In this case, the electrode forms (as seen from above) an integral contact grid, and a metal electrode will then possibly be preferred in so far as it will not form an obstacle to the light entering or exiting via the upper faces of the diodes. In this case, a transparent insulating layer 61 may cover the diodes 40 and the upper conductive layer 60. The surface of this transparent insulating layer 61 may be structured notably in order to improve optical focus and/or extraction, inter alia. Other variants are possible. Thus, the upper layer 60 may be a thin continuous layer that is at least partially transparent, over which a metal grid located facing the intermediate insulating layer 50 extends, this grid thus allowing the charge carriers to be better collected/extracted and the potentially high electrical resistivity of the thin layer 60 to be compensated for. The thin layer 60 may be made, apart from the materials indicated above, of doped amorphous silicon, this allowing the passivation of the upper face of the diodes to be improved.

Thus, as described in detail below, the optoelectronic device 1 comprises a matrix array of diodes 40 obtained from a readout substrate 10 by means of nucleation segments 30 made of a two-dimensional crystalline material, which make electrical contact with conductive segments 20 that are connected to the readout circuit 12. The diodes 40 are produced by van der Waals epitaxy from the two-dimensional material of the nucleation segments 30. They therefore have a crystal lattice that is not mechanically strained by that of the nucleation segments 30, nor by the readout substrate 10. Thus, the effective lattice parameter of the semiconductor of the diodes 40, in particular that of the lower portions making contact with the nucleation segments 30, is substantially equal to its value in the natural (unstrained) state. This is due to mechanical strains in the semiconductor of the diodes 40 relaxing correctly throughout the thickness thereof, thus leading to a low density of structural defects such as the misfit dislocations that result from possible plastic relaxation of strain. Thus, it is possible to produce doped semiconductor portions forming pn or pin junctions the thickness of which is no longer limited by a critical thickness from which plastic relaxation of mechanical strains usually occurs, thus improving the internal quantum efficiency of the diodes 40. Depending on the intended application, the composition of the semiconductor of interest of the diodes 40 may also be chosen to obtain the desired cut-off wavelength. Thus, the invention allows an InAsSb detector to be produced for a LWIR application, whereas a growth substrate having a lattice parameter suitable for this material for this application currently causes defects to be generated.

Moreover, the diodes 40 are pixelated from the epitaxial growth on the nucleation segments 30, which are separate from one another. Thus, the risk of degradation of the crystal quality of the semiconductor of the diodes 40, and notably of the sidewalls, is decreased since the diodes 40 are not pixelated via a step of growing a semiconductor stack followed by a step of localized etching to pixelate the diodes 40. The optical and/or electronic properties of the optoelectronic device 1 are thus improved.

Moreover, as explained above, the diodes 40 are produced from the readout substrate 10 by means of nucleation segments 30 made of two-dimensional material formed in contact with conductive segments 20. Thus, steps of hybridizing, i.e. of mechanically joining by transferring and electrically connecting, an optoelectronic chip and a control chip are avoided. Thus, the risks of misalignment and/or of loss of mechanical and therefore electrical contact between the interconnect pads of the control chip and the diodes 40 of the optoelectronic chip is avoided. It is then possible for the optoelectronic device 1 to comprise a matrix array of diodes 40 comprising a high number of diodes 40 of low pitch. In addition, the composition of the material of neighbouring diodes may be different from one diode to the next, permitting a multi-spectral device to be produced.

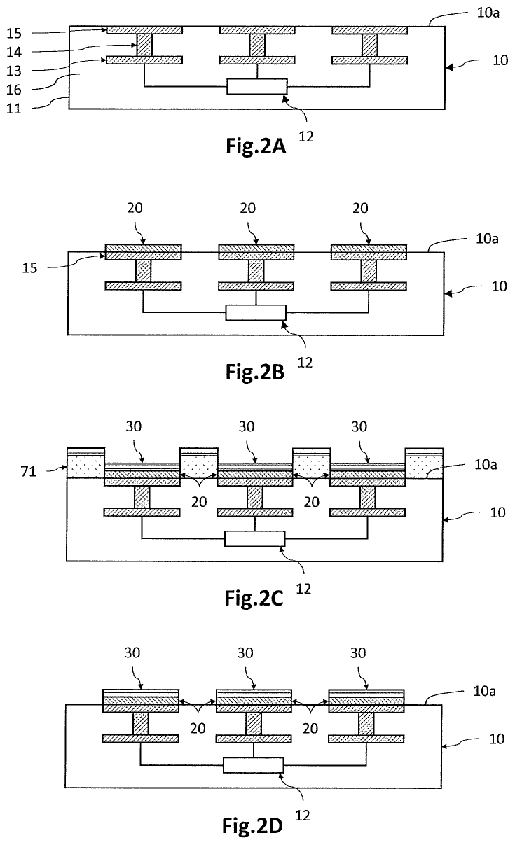

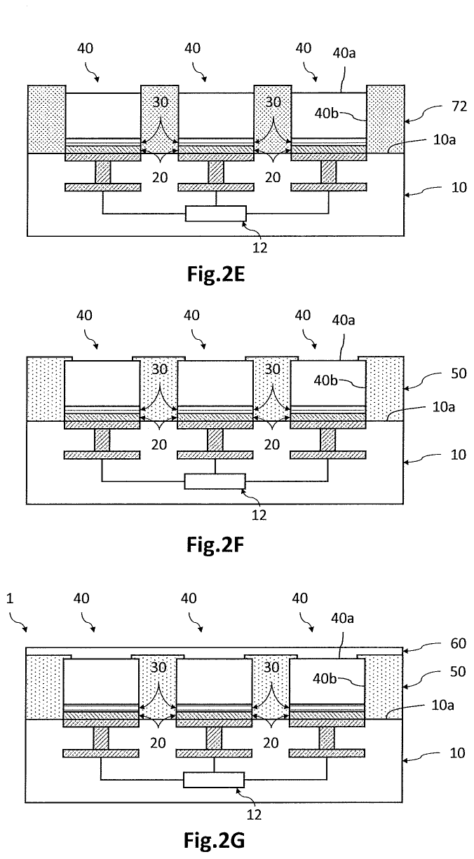

FIGS. 2A to 2G are schematic and partial views, in cross section, of various steps of a process for fabricating an optoelectronic device 1 comprising a matrix array of photodiodes 40, according to one variant of the embodiment illustrated in FIG. 1A.

With reference to FIG. 2A, a readout substrate 10, formed from a carrier substrate 11 containing a CMOS readout circuit 12, is produced. The readout circuit 12 comprises various segments 13, 15 of metal line, which are separated from one another in the XY plane by an inter-metal dielectric layer 16, which here is made of a silicon oxide. The segments 13, 15 of the various interconnect levels are connected to one another by conductive vias 14, and are thus connected to the readout circuit 12. Segments 15 of the metal line of the last interconnect level lie flush with the planar upper face 10a of the readout substrate 10.

With reference to FIG. 2B, conductive portions 20 are produced using conventional steps of depositing, photolithography and localized etching. In this example, said segments protrude with respect to the planar upper face 10a of the readout substrate 10, and are placed in contact with the segments 15 of the metal line of the last interconnect level. The upper face of the conductive segments 20 participates in the definition of the growth face of the readout substrate 10. In this example, these segments have lateral dimensions that are substantially equal to those of the segments of the metal line, but they may have different dimensions. The conductive segments 20 are here preferably made of gold. They here have a thickness of the order of 500 nm and lateral dimensions of the order of 10 μm. They are thus separate from one another in the XY plane and are suitable for biasing the diodes 40.

With reference to FIG. 2C, the nucleation segments 30 are produced on and in contact with the conductive segments 20. To this end, a first mask 71 here formed from a photoresist may be deposited beforehand. This mask 71 extends over the unoccupied surface of the planar upper face 10a of the readout substrate 10, i.e. between the conductive segments 20. This mask 71 preferably has a thickness larger than that of the conductive segments 20 and nucleation segments 30, and for example a thickness of the order of 1 μm. The nucleation segments 30 are made of a two-dimensional crystalline material. In the case where the conductive segments 20 are made of gold, the two-dimensional crystalline material is advantageously a sulfur-containing material, and possibly MoS₂, because of the high affinity between gold and sulfur, thus allowing the risk of delamination to be decreased. In addition, the two-dimensional crystalline material is here electrically conductive, so as to allow the diodes 40 to be biased. It may comprise a low number of atomic monolayers, and may for example be formed from a single monolayer, so as to promote the transmission of electrical current notably via the tunnel effect. The nucleation segments 30 may be produced by molecular beam epitaxy (MBE), by metal-organic chemical vapour deposition (MOCVD) or any other type of chemical vapour deposition (CVD), or by atomic layer deposition (ALD), inter alia. The temperature at which the nucleation segments 30 are produced is preferably lower than or equal to 400° C., so as to prevent any degradation of the readout circuit 12. The two-dimensional crystalline material is here deposited both on the upper face of the conductive segments 20 and on the upper face of the first mask.

With reference to FIG. 2D, the first mask is then removed, for example by lift-off. Thus a plurality of nucleation segments 30, which are made of a two-dimensional crystalline material, which are separate from one another in the XY plane, and which rest on and in contact with the conductive segments 20, are produced.

As a variant, the nucleation segments 30 may be formed by transferring a continuous layer made of a two-dimensional crystalline material, in particular when the growth face is planar and coincides with the planar upper face 10a of the readout substrate 10 (in other words when the conductive segments 20 do not protrude with respect to the planar upper face 10a but lie flush with the latter). The continuous layer made of two-dimensional crystalline material may be a continuous layer of graphene formed by graphitizing a SiC substrate of hexagonal crystal lattice by high-tension vacuum annealing, this continuous graphene layer then being transferred to the planar upper face 10a of the readout substrate 10. A step of localized etching of the continuous graphene layer is then carried out so as to obtain nucleation segments 30 that are separate from one another and located on and in contact with the conductive segments 20. In this respect, the article by Avouris et Dimitrakopoulos entitled “Graphene: synthesis and applications”, Materials Today, 03/2012, Vol. 15, No. 3, gives details of conventional techniques, and notably graphitization of an SiC substrate followed by transfer, allowing a continuous graphite layer to be produced.

With reference to FIG. 2E, the diodes 40 are produced by van der Waals epitaxy from the nucleation segments 30. To this end, a second mask 72, here a growth mask, is produced beforehand on the unoccupied surface of the planar upper face 10a of the readout substrate 10, i.e. between the conductive segments 20 and the nucleation segments 30. The growth mask 72 here has a thickness along the Z axis larger than or equal to the final thickness of the diodes 40, but as a variant it may have a thickness smaller than the final thickness of the diodes 40. It may be made of a dielectric, for example of a silicon oxide SiO or a silicon nitride SiN, inter alia.

The diodes 40 are then produced by epitaxial growth from the nucleation segments 30 of a semiconductor of interest, which is of II-VI, III-V or even IV type. This epitaxial growth step may comprise a nucleation phase followed by a phase of actual growth, these two phases differing from each other in the growth conditions and in particular in the value of the growth temperature. As a variant, in the epitaxial growth step the nucleation and growth phases may be one and the same phase.

The growth may be carried out using conventional epitaxial techniques such as metal-organic chemical vapour deposition (MOCVD) or any other type of chemical vapour deposition (CVD), molecular beam epitaxy (MBE), hydride vapour phase epitaxy (HVPE), atomic layer epitaxy (ALE), atomic layer deposition (ALD), or even evaporation or cathode sputtering. By way of illustration, the diodes 40 are produced by MBE at a growth temperature of the order of about 400° C., so as to prevent any degradation of the readout circuit 12.

Thus, the semiconductor of the diodes 40 is bonded to the nucleation segments 30 by weak bonds of van der Waals type, and not by covalent or ionic bonds. The semiconductor may thus nucleate substantially at its natural lattice parameter, and is therefore substantially not strained by any lattice mismatch between the nucleation segments 30 and the semiconductor.

With reference to FIG. 2F, the intermediate insulating layer 50 is produced. To do this, the growth mask 72 is first removed, for example by selective chemical processing. In this example, all the thickness of the latter is removed; however, as a variant, and as detailed below, a lower portion of the growth mask, i.e. a portion located in contact with the readout substrate 10, may be kept. The intermediate insulating layer 50, which is made of at least one electrical insulator, is then deposited so as to make contact with the lateral faces 40b of the diodes 40 over all the thickness of the latter, and to fill the space between the diodes 40. By way of example, in the case of diodes 40 based on CdHgTe, the intermediate insulating layer 50 may thus be formed from a passivating sublayer made of CdTe that makes contact with the lateral face 40b of the diodes 40, which is coated with a filling layer made of ZnS, SiO or SiN, inter alia, which covers the passivating sublayer and fills the inter-diode space. The passivating sublayer may also be produced by oxidizing the semiconductor of the diodes 40. As a variant, in the case of diodes 40 based on a III-V semiconductor compound, the intermediate insulating layer 50 may be made of a single material, for example of a silicon oxide, a silicon nitride, a silicon oxynitride, or of Al2O3, inter alia. The intermediate insulating layer 50 ends substantially level with the upper face 40a of the diodes 40. In this example, it covers a portion of the lateral border of the upper face 40a.

With reference to FIG. 2G, the upper conductive layer 60 is produced so that it makes contact with the upper face 40a of the diodes 40. In this example, the upper conductive layer 60 entirely covers the upper face 40a of the diodes 40. It is therefore made of a material that is not only electrically conductive but also transparent to the electromagnetic radiation of interest. The material chosen notably depends on the central wavelength of the detection or emission spectral range of the diodes 40. The upper conductive layer 60 may be produced by CVD, by ALD for example, by ion beam sputtering (IBS), or even by sol-gel deposition, inter alia. The upper conductive layer 60 is connected to the readout circuit 12 of the readout substrate 10.

Thus, this fabricating process allows a matrix array of diodes 40 to be produced on a readout substrate 10 by van der Waals epitaxy from a plurality of nucleation segments 30 made of a two-dimensional crystalline material, said segments being located in contact with conductive segments 20 that are connected to the readout circuit 12. As mentioned above, this avoids the problems that may arise with hybridizing processes involving chip transfer, and notably the problem of misalignment between the respective connection pads of the control chip and of the optoelectronic chip, and also avoids the risk of faulty electrical contact between the diodes 40 and the readout circuit 12. Moreover, the crystal quality of the semiconductor of the diodes 40 is improved because the latter is no longer strained by the lattice parameter of the nucleation material, because van der Waals epitaxy is employed. The fabricating process also ensures a pixelation of the diodes 40 from the epitaxial growth, and does not require localized etching of a semiconductor stack of continuous crystalline layers to form the diodes 40, as is notably the case in the case of loophole fabricating processes. This fabricating process thus allows a matrix array of diodes 40 of high crystal quality comprising a high number of diodes 40 of low pitch to be produced.

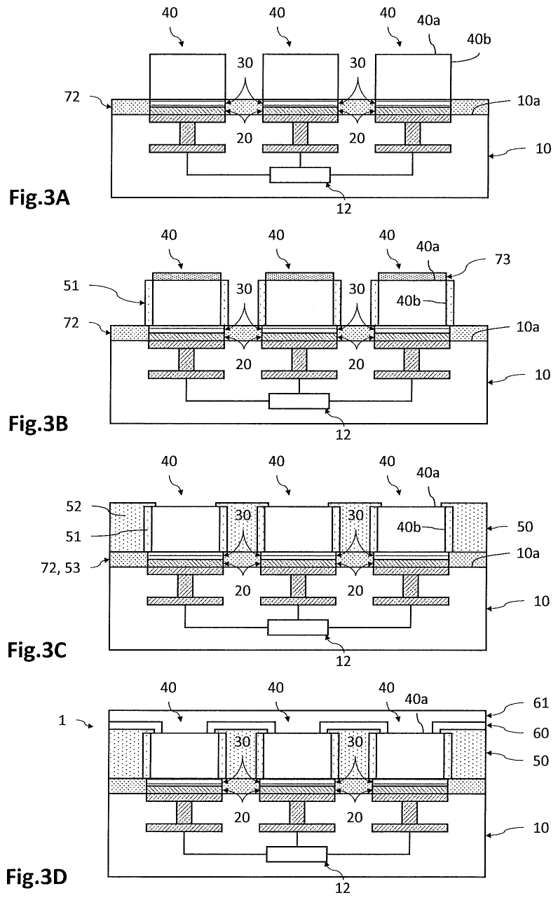

FIGS. 3A to 3D are schematic and partial views, in cross section, of various steps of a process for fabricating an optoelectronic device 1 comprising a matrix array of diodes 40 according to the embodiment illustrated in FIG. 1B.

The steps used to produce the readout substrate 10, the conductive segments 20 and the nucleation segments 30 are identical or similar to those described with reference to FIGS. 2A to 2D, and are not described again here.

With reference to FIG. 3A, the diodes 40 are produced by van der Waals epitaxy from the nucleation segments 30 made of a two-dimensional crystalline material. To this end, a growth mask 72 is produced beforehand on the unoccupied surface of the growth face of the readout substrate 10, i.e. between the conductive segments 20 and the nucleation segments 30. The growth mask 72 here has a thickness along the Z axis smaller than the final thickness of the diodes 40, but larger than or equal to the thickness of the conductive segment 20 and of the nucleation segment 30. Thus, the growth mask 72 makes it possible to guarantee that each nucleation segment 30 is correctly positioned with respect to the subjacent conductive segment 20 in the XY plane. By way of example, the growth mask 72 may have a thickness of about 500 nm. It may be made of a dielectric, for example of a silicon oxide SiO or a silicon nitride SiN, inter aria.

With reference to FIG. 3B, a passivating sublayer 51 of the intermediate insulating layer 50 is then produced. To this end, a mask 73, here a photoresist, is first deposited locally so as to solely cover the upper face 40a of the diodes 40. Thus, the lateral face 40b of the diodes 40 is left free, i.e. uncovered. An electrochemical oxidation is then carried out so as to form a passivating sublayer 51 made of an oxide of the semiconductor of the diodes 40. This sublayer 51 thus covers the lateral face 40b of the corresponding diode 40, preferably continuously.

With reference to FIG. 3C, production of the intermediate insulating layer 50 is then finished off. Thus, the photoresist 73 is removed and the growth mask 72 is kept. The latter then forms the lower insulating portion 53 of the intermediate insulating layer 50. The filling layer 52 is then deposited so as to cover the lower insulating portion 53 and the passivating sublayers 51. The filling layer 52 lies substantially flush with the upper face of the diodes 40. It here covers a lateral border of the upper face 40a of the diodes 40.

With reference to FIG. 3D, the upper conductive layer 60 is then produced so that it makes contact with the upper face 40a of each diode. In this example, the upper conductive layer 60 does not entirely cover the upper faces 40a but solely covers a lateral border of the latter and forms an electrode that is preferably of integral character (contact common to all the diodes). Thus potential partial absorption of the electromagnetic radiation of interest by the upper conductive layer 60 is limited. A protective layer 61, which is made of a material that is electrically insulating and transparent to the electromagnetic radiation of interest, is then deposited so as to continuously cover the diodes 40 and the upper conductive layer 60. It surface may be structured to perform a defined optical function (light extraction, formation of the light beam emitted or received, etc.).

Thus, an optoelectronic device 1 comprising a matrix array of diodes 40, said diodes being produced from a readout substrate 10 and having a good crystal quality, is obtained by means of nucleation segments 30 made of a two-dimensional crystalline material, said segments being placed in contact with conductive segments 20 of the readout substrate 10.

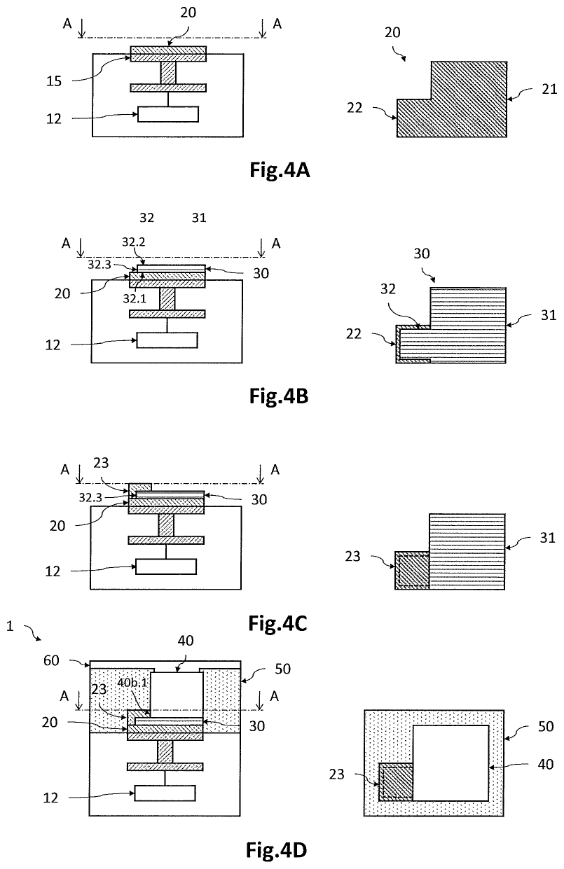

FIGS. 4A to 4D are schematic and partial views, in cross section and of the plane A-A seen from above, of various steps of a process for fabricating an optoelectronic device 1 according to one variant embodiment. The fabricating process is similar to those described above, and differs therefrom notably in that it allows the electrical conduction between the conductive segments 20 and the nucleation segments 30 to be improved.

Certain steps are identical or similar to those described above and are not described again here. For the sake of clarity, the steps of production of a single diode of the matrix array are shown here.

With reference to FIG. 4A, a conductive segment 20 that comprises a main zone 21 intended to be coated with the epitaxially grown diode, and a lateral zone 22 that extends, in the XY plane, from the main zone 21, is firstly produced for each diode 40. The lateral zone 22 has dimensions in the XY plane that are preferably smaller than those of the main zone 21, and is intended to improve the electrical contact with the nucleation segment 30.

With reference to FIG. 4B, the nucleation segment 30 is produced, as described above, so as to be located on and in contact with the conductive segment 20, both in the main zone 21 and in the lateral zone 22 of said segment 20. It thus comprises a lateral portion 32, which is located on and in contact with the lateral zone 22, and which extends laterally from a main portion 31. The lateral portion 32 does not entirely cover the lateral zone 22, so that a lateral face of the nucleation segment 30 is located therein. More precisely, each main zone 21 of the conductive segment 20 is coated with the nucleation segment 30, but the lateral zone 22 is coated only partially with the nucleation segment 30. Each lateral portion 32 of the nucleation segment 30 thus has a lateral face 32.3 located above the lateral zone 22 of the conductive segment 20, which face connects a lower face 32.1 of the nucleation segment 32, which makes contact with the conductive segment 20, and an opposite upper face 32.2.

With reference to FIG. 4C, a lateral upper portion 23 of the conductive segment 20 is then produced using conventional steps of depositing, photolithography and etching, said lateral upper portion making contact with the edge face, i.e. the lateral face 32.3, of the lateral portion 32 of the nucleation segment 30, and advantageously covering the lateral portion 32. This lateral upper portion 23 of the conductive segment makes continuous contact with the lateral zone 22 and with the lateral face of the nucleation segment 30, and leaves the main zone 21 free. The lateral upper portion 23 makes contact with the subjacent conductive segment 20, and contact with the lateral face 32.3 of the nucleation segment 30, and advantageously contact with the upper face 32.2. The nucleation layer 20 may thus be considered to be formed from a lower portion (indicated by the reference 20 in the figures) and by the lateral upper portion 23.

With reference to FIG. 4D, production of the optoelectronic device 1 is finished off as described above via steps of van der Waals epitaxy of the diodes 40 from the main portion 31 of the nucleation segments 30, of producing the intermediate insulating layer 50, and of producing the upper conductive layer 60. These steps are identical or similar to those described above and are not described again here. As a variant, the step of van der Waals epitaxy may be carried out before the step of producing the lateral upper portions 23. The diodes 40 cover the main zone 21 but do not cover the lateral zone 22. The lateral upper portion 23 advantageously makes contact with a lower surface 40b.1 of a lateral face of the diode 40.

Thus, an optoelectronic device 1 is obtained in which the electrical contact between the conductive segments 20 and the nucleation segments 30 is improved.

Specifically, it will be understood that the electrical contact in the plane between the conductive segments 20 and the nucleation segments 30 may be resistive depending on the materials used. However, it should be obvious that the electrical contact may be less resistive when it is made notably to the edge face of the nucleation segments 30, i.e. to the lateral face that connects the lower and upper faces of the nucleation segments 30. The upper lateral portion 23 of the conductive segments 20 comprises to this end a zone that makes contact with the edge face of the nucleation segments 30, thus improving electrical conduction between the conductive segment and the nucleation segment. The performance of the optoelectronic device 1 is thus equivalent, or even improved.

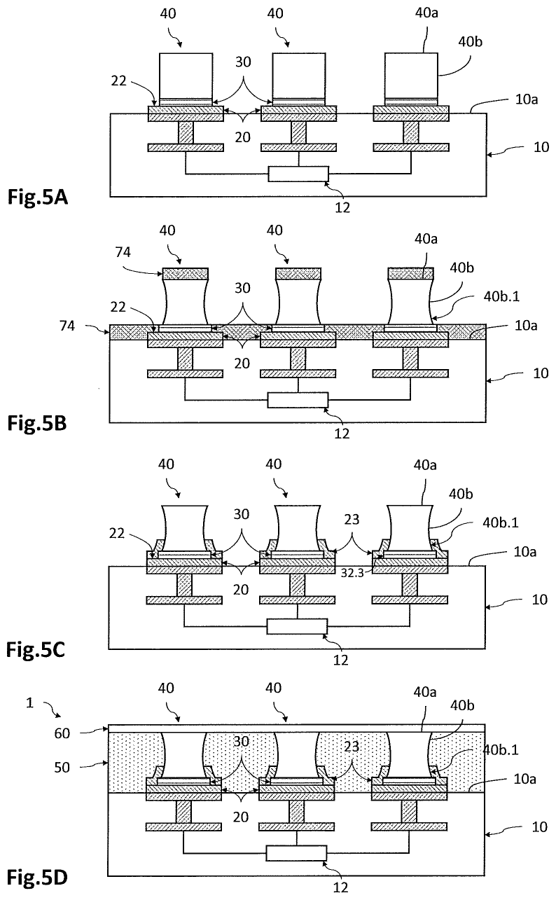

FIGS. 5A to 5D are schematic and partial views, in cross section, of various steps of a process for fabricating an optoelectronic device 1 according to another embodiment. The fabricating process is similar to those described above, and differs therefrom notably in that it allows the electrical conduction between the conductive segments 20 and the diodes 40 to be improved. Certain steps are identical or similar to those described above and are not described again here.

With reference to FIG. 5A, a matrix array of diodes 40 is first produced by van der Waals epitaxy from nucleation segments 30. Care will be taken to ensure that the diode junctions are preferably positioned in proximity to or in the top portion of the segments 40. The conductive segments 20 each comprise a lateral zone 22 an upper surface of which is left free, i.e. not coated with the nucleation segment 30 and with the diodes 40. The lateral zone 22 here extends right round the outline of the diodes 40, but may be present only on one portion of the outline. Each nucleation segment 30 thus has a lateral face 32.3 located above the lateral zone 22 of the conductive segment 20, which connects a lower face 32.1 of the nucleation segment 30, which makes contact with the conductive segment 20, and an opposite upper face 32.2.

With reference to FIG. 5B, the lateral face 40b of the diodes 40 is isotropically and selectively etched so as to give the lateral faces 40b an inclined lower surface 40b.1. To this end, a photoresist is deposited so as to cover the upper face 40a of the diodes 40 and the conductive segments 20, the nucleation segments 30 and the readout substrate 10. Thus, the lateral face 40b of the diode is left free. The selective etching is carried out using an etchant that reacts with the semiconductor of the diodes 40. The lateral face 40b of the diodes then sees a narrowing of its diameter in a median zone of the diodes 40 along the Z axis. Thus, it has an inclined, or in other words concave, lower surface 40b.1 that extends from the nucleation segment 30 along the Z axis.

With reference to FIG. 5C, a lateral upper portion 23 of the conductive segments 20, which portion makes continuous contact with the lateral zone 22 of the conductive portion and with the inclined lower surface 40b.1, is then produced using conventional steps of depositing, photolithography and etching. To this end, the diodes 40 and the readout substrate 10 are coated with a photoresist (not shown), which is etched locally only in the location of the inclined lower surfaces 40b.1 and of the free upper surface of the lateral zone 22 of the conductive segments 20. The edge face of the nucleation segments 30 is also freed. Next, a conductor, which is preferably identical to that of the conductive segments 20, for example gold, is deposited so as to form a lateral upper portion 23 that continuously covers, for each diode, the free upper surface of the lateral zone 22 of the conductive segment and the inclined lower surface 40b.1 of the diode. The edge face of the nucleation segment 30 is also covered by the lateral upper portion 23. The photoresist and the gold layer covering it is then removed by lift-off. The lateral upper portion 23 makes contact with the subjacent conductive segment 20 and contact with the lower surface 40b.1 of the diode 40, and, here, contact with the lateral face 32.3 of the nucleation segment 30.

With reference to FIG. 5D, production of the optoelectronic device 1 is finished off as described above via steps of producing the intermediate insulating layer 50 and of producing the upper conductive layer 60. These steps are identical or similar to those described above and are not described again here.

Thus, an optoelectronic device 1 is obtained in which the electrical conduction between the conductive segments 20 and the diodes 40 is improved. Specifically, it will be understood that the electrical contact in the plane between the nucleation segments 30 and semiconductor of the diodes 40 may be resistive depending on the materials used. Thus, the lateral upper portion 23 of the conductive segments 20 allows electrical conduction with the diodes 40 to be improved by forming an additional zone of electrical conduction on the border of the nucleation segments 30. The performance of the optoelectronic device 1 is thus equivalent, or even improved.

Particular embodiments have just been described. Various variants and modifications will appear obvious to anyone skilled in the art.

Thus, the peripheral lateral portion of the conductive segments 20 described with reference to FIGS. 4D and 5D may extend over all the border of the diodes 40 in the XY plane, or extend only over only one portion of this border.

The diodes 40 may be identical to one another, notably in the case of monospectral emission or detection. As a variant, they may differ from one another in the composition of the semiconductor, notably in the case of a multispectral use of the optoelectronic device 1. In this case, a plurality of successive epitaxy steps are applied while taking care to mask, each time, zones that are not intended to accommodate the material in the process of being deposited.

1. Process for fabricating an optoelectronic device comprising a plurality of diodes, comprising the following steps:
providing a readout substrate containing a readout circuit comprising metal lines separated from one another by inter-metal dielectric layers, and having a growth face defined by a plurality of conductive segments made of at least one metal, which segments are separate from one another and connected to the readout circuit;
producing, on the growth face, a plurality of nucleation segments made of a two-dimensional crystalline material, which segments are separate from one another, said segments resting in contact with the conductive segments;
producing, by epitaxy from the nucleation segments, the plurality of diodes.

2. Process according to claim 1, wherein the readout substrate has a planar upper face, the conductive segments protruding with respect to the planar upper face and resting in contact with segments of the metal lines of the readout circuit.

3. Process according to claim 1, wherein the readout substrate has a planar upper face, the conductive segments lying flush with the planar upper face and forming segments of the metal lines of the readout circuit.

4. Process according to claim 1, wherein each conductive segment comprises:
a main zone, coated with the nucleation segment, and intended to be coated with the diode, and
a lateral zone, partially coated with the nucleation segment so that the latter has a lateral face connecting lower and upper faces of the nucleation segment, and intended not to be coated with the diode and extending, in a plane parallel to the readout substrate, from the main zone,
the process comprising a step of producing a lateral upper portion of the conductive segment so that it makes continuous contact with the lateral zone and continuous contact with the lateral face of the nucleation segment.

5. Process according to claim 1, wherein each conductive segment comprises:
a main zone, coated with the nucleation segment and with the diode, and
a lateral zone, which is not coated with the diode and which extends, in a plane parallel to the readout substrate, from the main zone,
the process comprising a step of producing a lateral upper portion of the conductive segment so that it makes continuous contact with the lateral zone and continuous contact with a lower surface of a lateral face of the diode.

6. Process according to claim 5, comprising, prior to the step of producing the lateral upper portion, a step of partially etching the diodes isotropically and selectively from a lateral face of the diodes, the lateral face of the diodes connecting a lower face making contact with the nucleation segments and an opposite upper face, so that the lower surface is inclined with respect to an axis orthogonal to the plane of the readout substrate.

7. Process according to claim 1, comprising a step of producing an intermediate insulating layer, making contact with the diodes in a plane parallel to the readout substrate, and filling the space between the diodes.

8. Process according to claim 7, wherein the intermediate insulating layer comprises a passivating sublayer making contact with a lateral face of the diodes, and a filling layer covering the passivating sublayer and filling the inter-diode space.

9. Optoelectronic device, comprising:
a readout substrate, containing a readout circuit, and comprising a plurality of conductive segments that are made of at least one metal, said conductive segments being separate from one another, defining a growth face of the readout substrate and being connected to the readout circuit, the latter comprising metal lines that are separated from one another by inter-metal dielectric layers;
a plurality of nucleation segments, which are separate from one another, placed in contact with the conductive segments and made of a two-dimensional crystalline material;
a plurality of diodes, located in contact with the nucleation segments.

10. Optoelectronic device according to claim 9, wherein the diodes are based on a semiconductor of interest, which is an element or a compound of II-VI, III-V or IV type.

11. Optoelectronic device according to claim 9, wherein each conductive segment comprises a lateral zone that is partially coated by the nucleation segment, and a lateral upper portion that makes continuous contact with the lateral zone and continuous contact with a lateral face of the nucleation segment.

12. Optoelectronic device according to claim 9, wherein each conductive segment comprises a lateral zone not coated with a diode, and a lateral upper portion that makes continuous contact with the lateral zone and continuous contact with a lower surface of a lateral face of the diode.

13. Optoelectronic device according to claim 9, wherein at least two diodes are made of a semiconductor having different compositions.

14. Optoelectronic device according to claim 9, wherein the nucleation segments are made of tungsten or molybdenum sulfide, and the conductive layers are made of gold.
